(19) United States
(12) Patent Application Publication
(10) Pub. No.: US 2017/0062569 A1
(43) Pub. Date: Mar. 2, 2017

(54) SURFACE ENCAPSULATION FOR WAFER BONDING

(71) Applicant: Intel Corporation, Santa Clara, CA (US)

(72) Inventors: Kimin JUN, Hillsboro, OR (US); Willy RACHMADY, Beaverton, OR (US); Glenn GLASS, Portland, OR (US); Anand MURTHY, Portland, OR (US)

(21) Appl. No.: 15/119,119

(22) PCT Filed: Jun. 13, 2014
(86) PCT No.: PCT/US14/42316

§ 371 Date: Aug. 15, 2016

(51) Int. Cl. H01L 29/161; H01L 21/02; H01L 25/065; H01L 23/528; H01L 23/29; H01L 25/00; H01L 23/522; H01L 21/56; H01L 23/31

(52) U.S. Cl. CPC H01L 29/161; H01L 21/56; H01L 21/02532; H01L 25/0657; H01L 23/3171; H01L 23/298; H01L 25/50; H01L 23/5226; H01L 23/5283

(57) ABSTRACT

Techniques are disclosed for wafer bonding with an encapsulation layer. A first semiconductor substrate is provided. An encapsulation layer is then formed on top of the first semiconductor substrate. The encapsulation layer is formed of an encapsulation material that creates a stable oxide when exposed to an oxidizing agent. A first bonding layer is formed on top of the encapsulation layer. Next, a second semiconductor substrate is provided. A second bonding layer is formed on top of the second bonding layer. Thereafter, the first semiconductor substrate is bonded to the second semiconductor substrate by attaching the first bonding layer to the second bonding layer.

### TECHNICAL FIELD

Embodiments of the present invention relate generally to semiconductor wafer bonding processes. More particularly, embodiments of the present invention relate to surface encapsulation layers for semiconductor wafer bonding processes.

### BACKGROUND

Silicon has been a universally adopted semiconductor material for fabricating semiconductor devices in modem electronics, such as tablets, cell phones, and laptop/notebook computers. Technological advancement in this industry, however, has progressed to a point where the capabilities of silicon as a base material for the fabrication of semiconductor devices are becoming insufficient given the demands and expectations of the modern consumer, such as lower power consumption and higher performance. As a result, alternative materials are being explored in an effort to find a suitable replacement for, or complement to, silicon. Research has revealed that germanium is one of the most promising such semiconductor materials.

### BRIEF DESCRIPTION OF THE DRAWINGS

FIG. 1A illustrates a cross-sectional view of a conventional heterogeneous bonded wafer structure having a first substrate and a second substrate.

FIG. 1B illustrates a cross-sectional view of conventional fins formed from a conventional heterogeneous bonded wafer structure.

FIG. 2A illustrates a cross-sectional view of a heterogeneous bonded wafer structure with an encapsulation layer, in accordance with an embodiment of the invention.

FIG. 2B illustrates a cross-sectional view of fins formed from a heterogeneous bonded wafer structure with an encapsulation layer, in accordance with an embodiment of the invention.

FIGS. 3A-3D illustrate cross-sectional views of a method of preparing a first substrate for bonding with a second substrate, in accordance with an embodiment of the invention.

FIGS. 4A-4C illustrate cross-sectional views of a method of preparing a second substrate for bonding with a first substrate, in accordance with an embodiment of the invention.

FIGS. 5A-5B illustrate cross-sectional views of a method of bonding a first substrate with a second substrate, in accordance with an embodiment of the invention.

FIG. 6A illustrates an isometric view of a non-planar finFET device including a fin having an encapsulation layer heterogeneously attached to a substrate by an oxide layer, according to an embodiment of the invention.

FIG. 6B illustrates a cross-sectional view of a non-planar finFET device including a fin having an encapsulation layer heterogeneously attached to a substrate by an oxide layer, according to an embodiment of the invention.

FIG. 7 illustrates an interposer implementing one or more embodiments of the invention.

FIG. 8 illustrates a computing device built in accordance with an embodiment of the invention.

### DETAILED DESCRIPTION

Described herein are bonded substrate stacks including an encapsulation layer and methods of their fabrication. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Embodiments of the invention are directed to methods of incorporating an encapsulation layer for bonding a first substrate to a second substrate. In one embodiment of the invention, a first substrate is provided. In an embodiment, the first substrate is formed of a semiconductor material that creates sub-oxides when oxidized. In an embodiment, the semiconductor material is germanium. An encapsulation layer is then formed on a top surface of the first substrate. Afterwards, a first bonding oxide layer is then deposited on the encapsulation layer. The encapsulation layer prevents oxidation of the first substrate by prohibiting the first bonding oxide layer from making contact with the first substrate. In an embodiment, the encapsulation layer is formed of a material that creates a stable oxide when oxidized. In an embodiment, the material is silicon. A second substrate, such as a silicon substrate, is provided. A second bonding oxide layer is deposited on a top surface of the second substrate. The second substrate and the first substrate are then bonded together by attaching the first bonding oxide layer to the second bonding oxide layer. The encapsulation layer prevents oxidation of the first substrate during bonding, thus creating a robust bond between the first and second substrates by substantially minimizing the potential for delamination of the first substrate from the second substrate.

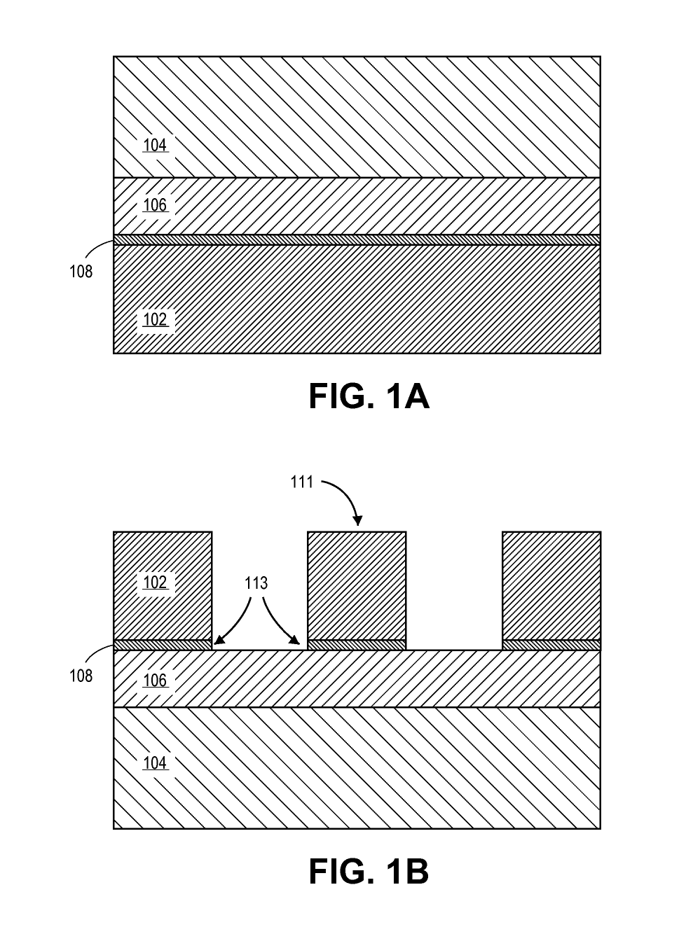

As shown in FIG. 1A, techniques for wafer bonding utilize a thin oxide layer 106 to attach a germanium substrate 102 with another substrate 104 formed of a different semiconductor material, such as silicon. When the oxide layer 106 is deposited on bare germanium, oxidation may naturally occur at the interface between the oxide layer 106 and the germanium substrate 102, thereby forming a thin layer of germanium oxide 108. Additionally, when the oxide layer 106 chemically bonds the semiconductor substrate 104 to the germanium substrate 102, water molecules are created as a by-product of the chemical bonding. The water molecules further oxidize the germanium substrate as well as dissolve the germanium oxide layer formed from the deposition process. Downstream semiconductor processes may also result in further oxidation of the germanium substrate. For instance, as shown in FIG. 1B, fins 111 may be formed by patterning the germanium substrate 102. By forming the fins 111, exposed interface regions 112 between the germanium substrate 102 and the oxide layer 106 may allow further oxidation of the germanium substrate 102 during downstream semiconductor processes. The layer of germanium oxide 108 is an unstable oxide layer that causes poor adhesion between the germanium substrate 102 and the silicon substrate 104. Additionally, the layer of germanium oxide 108 is easily dissolved in water. As such, the germanium substrate 102 is easily separated from the silicon substrate 104 by delamination from the oxide layer 106.

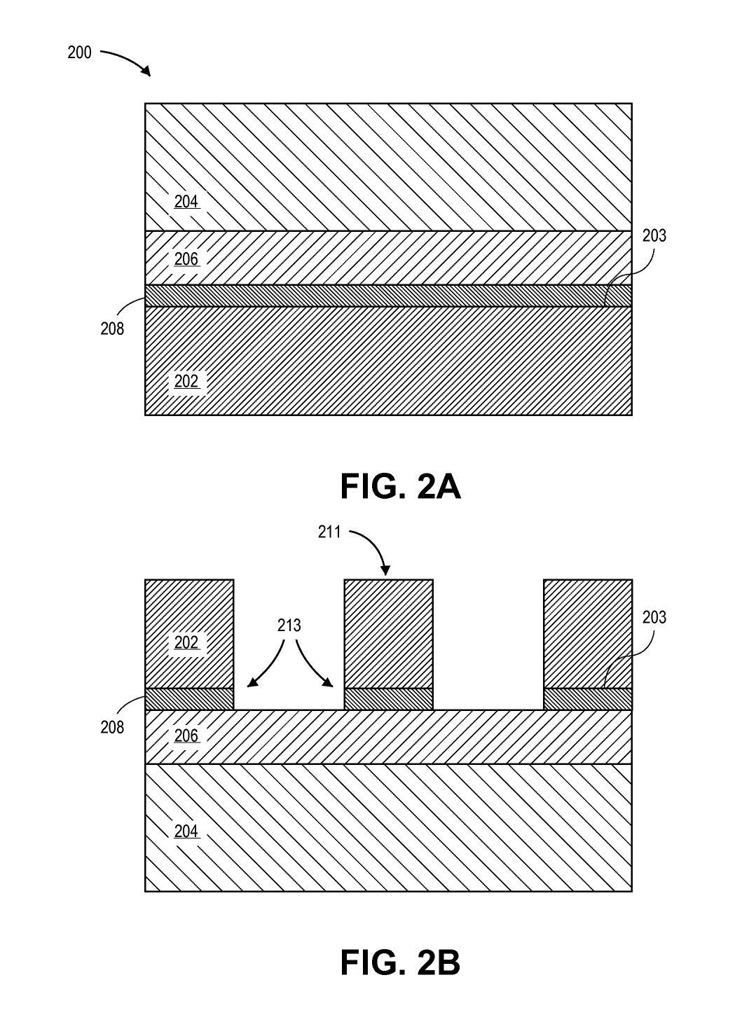

FIG. 2A illustrates a cross-sectional view of a heterogeneous bonded substrate stack 200 with an encapsulation layer 208, in accordance with an embodiment of the invention. In an embodiment, the first substrate 202 is a semiconductor material that lacks a stable oxide phase. That is, the semiconductor material forms an unstable oxide material when exposed to an oxidizing agent such as oxygen (O₂) and/or water (H₂O). In an embodiment, the first semiconductor material is germanium. A second substrate 204 is provided. The second substrate 204 may be any suitable substrate used for semiconductor fabrication. In an embodiment, the second substrate 204 is a bulk monocrystalline silicon substrate.

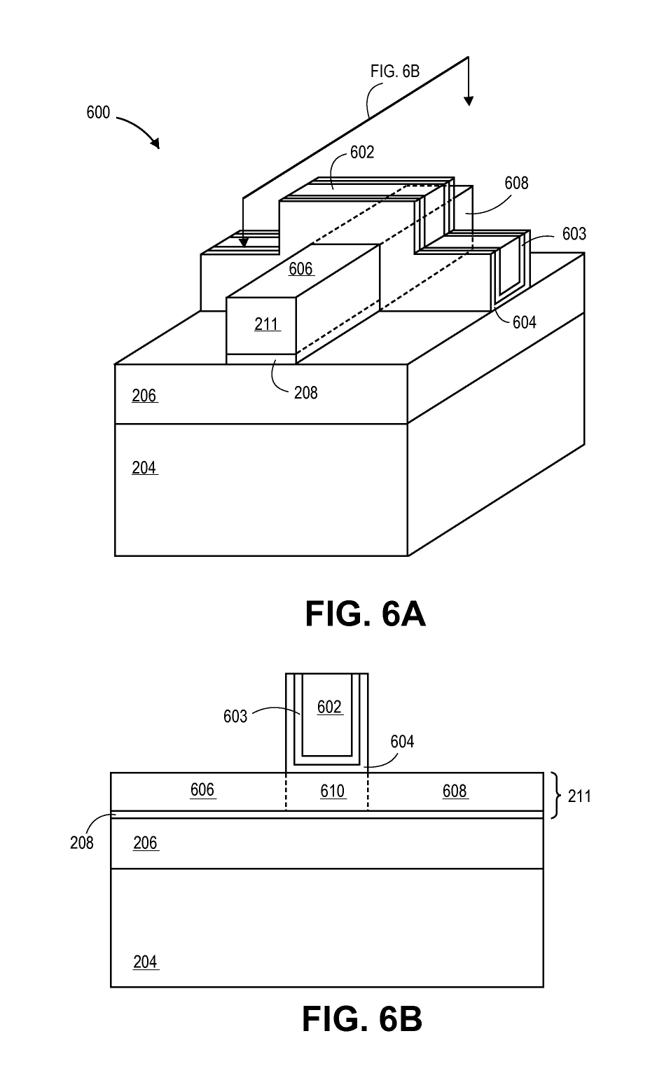

A bonded oxide layer 206 is disposed between the first substrate 202 and the second substrate 204. In an embodiment, the bonded oxide layer 206 is disposed directly between the second substrate 204 and an encapsulation layer 208. The bonded oxide layer 206 attaches the encapsulation layer 208 and the first substrate 202 to the second substrate 204 to form a heterogeneous structure, such as the heterogeneous bonded substrate stack 200. The heterogeneous bonded substrate stack 200 may then be used to form a semiconductor device or a plurality of semiconductor devices, such as a non-planar finFET device illustrated in FIG. 6. The bonded oxide layer 206 may be formed of any suitable material capable of bonding substrates together. In an embodiment, the bonded oxide layer 206 is formed of a silicon oxide (SiOₓ). In a particular embodiment, the bonded oxide layer 206 is formed of silicon dioxide (SiO₂). The bonded oxide layer 206 may be composed of two separate bonding oxide layers that have been fused together by a bonding process, such as an oxide diffusion bonding process.

The encapsulation layer 208 is disposed directly on the top surface 203 of the first substrate 202. The encapsulation layer 208 prevents oxidation of the first substrate 202, such as a germanium substrate, during deposition of oxide material. Additionally, the encapsulation layer 208 absorbs water by-products created during the oxide diffusion bonding process. The encapsulation layer 208 may also minimize oxidation of the first substrate 202 from downstream semiconductor processes. For example, as shown in FIG. 2B, fins 211 may be formed by patterning the first substrate 202. By forming the fins 211, exposed interface regions 213 near the edge of the fins 211 may be susceptible to exposure to water from downstream semiconductor processes. However, because unstable oxide does not exist at the interface between the first substrate 202 and the encapsulation layer 208, the fins 211 are not easily delaminated. Essentially, the encapsulation layer 208 acts as a passivation layer to prevent and/or minimize oxidation of the first substrate 202 at the interface. Preventing and/or minimizing oxidization of the first substrate allows a robust bond to be formed between the second substrate 204 and the first substrate 202. In embodiments, the encapsulation layer 208 is formed of a material that forms a stable oxide phase when exposed to an oxidizing agent such as O₂ and/or H₂O. The encapsulation layer may be formed to have a thickness sufficient to prevent oxidation of the first substrate 202. In an embodiment, the encapsulation layer 208 has a thickness in the range of 2 to 6 nm. In a particular embodiment, the encapsulation layer 208 has a thickness of about 4 nm. Additionally, in embodiments, the encapsulation layer 208 is formed of a material that can be heteroepitaxially grown on the first substrate 202. In an embodiment, the encapsulation layer 208 is formed of a material that forms a stable oxide when oxidized. In an embodiment, the encapsulation layer is formed of silicon. In a particular embodiment, the encapsulation layer 208 is epitaxial silicon.

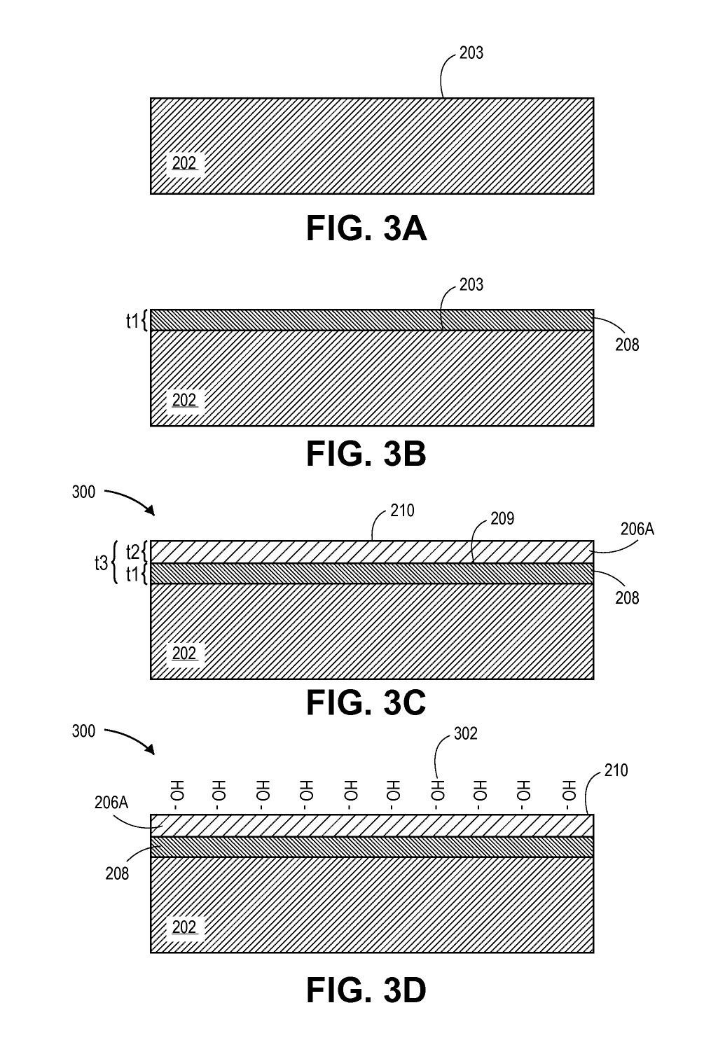

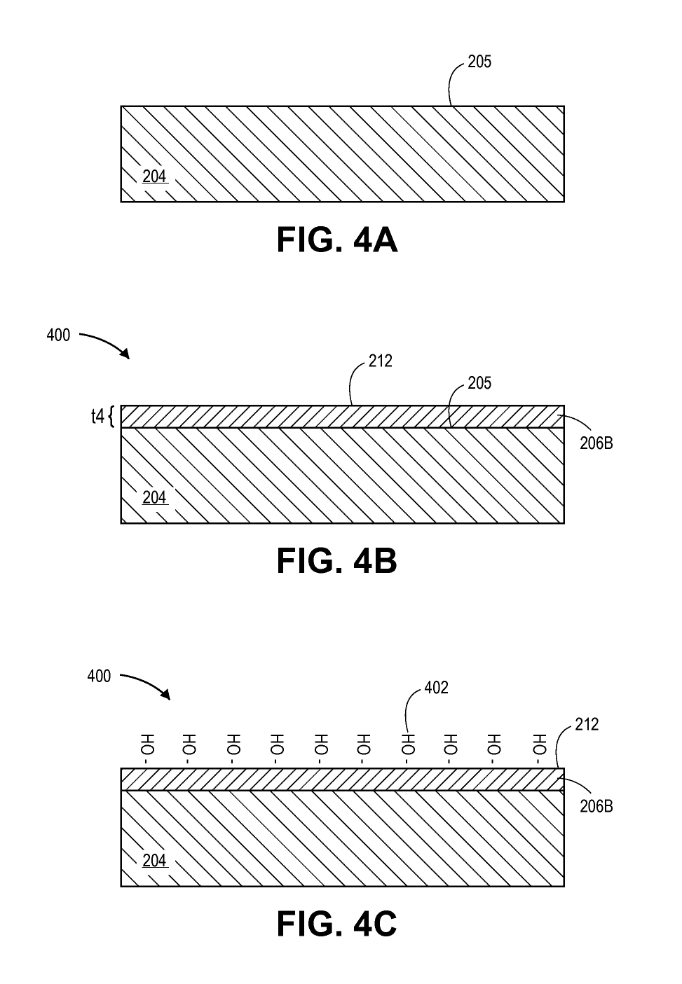

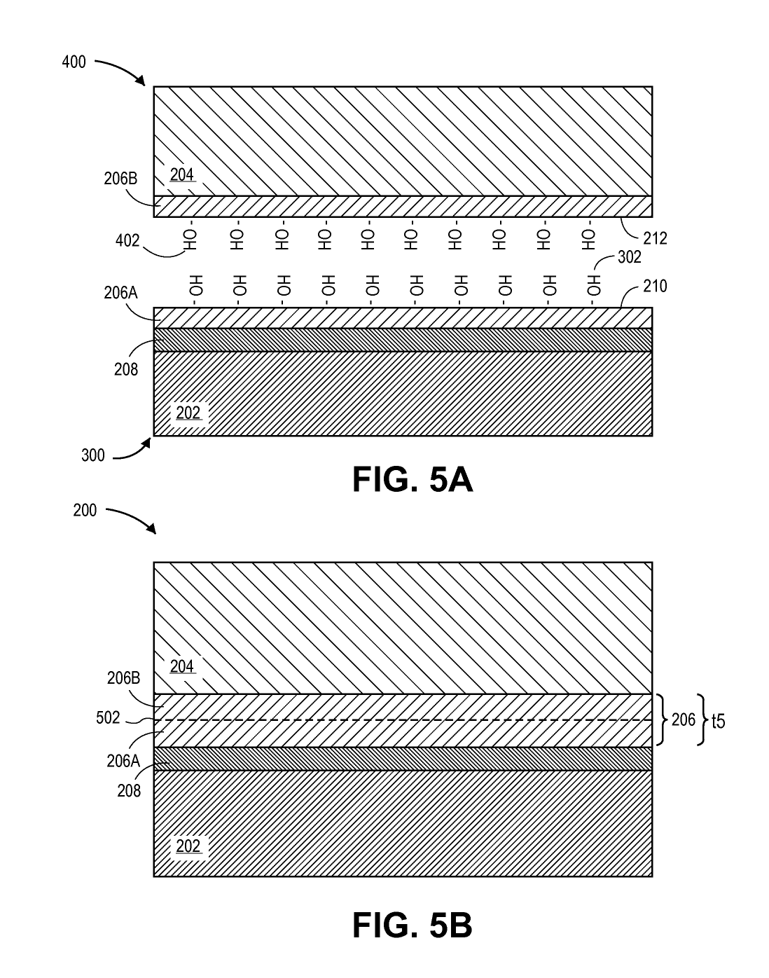

FIGS. 3A-5B illustrate a method of forming a heterogeneous bonded substrate stack 200 according to embodiments of the invention. More specifically, FIGS. 3A-3D illustrate cross-sectional views of a method of forming a first bonding substrate 300 for bonding with a second bonding substrate 400, in accordance with embodiments of the invention. FIGS. 4A-4C illustrate cross-sectional views of a method of forming the second bonding substrate 400 for bonding with the first bonding substrate 300, in accordance with embodiments of the invention. FIGS. 5A-5B illustrate cross-sectional views of a method of bonding the first bonding substrate 300 with the second bonding substrate 400, in accordance with embodiments of the invention.

With reference now to FIGS. 3A-3D, a method of forming a first bonding substrate 300 is illustrated. In FIG. 3A, a first substrate 202 with a top surface 203 is provided. In an embodiment, the first substrate 202 is formed of a material that lacks a stable oxide phase. That is, the material forms an unstable oxide material when exposed to an oxidizing agent such as O₂ and/or H₂O. The unstable oxide material may be a sub-oxide material that is less than stoichiometric ideal. For example, a stoichiometric ideal germanium oxide (GeO₂) may have an oxygen-to-germanium ratio of 2:1. A less than non-stoichiometric ideal germanium oxide (e.g., GeOₓ, where x is less than 2) may have an oxygen-to-germanium ratio of less than 2:1 (i.e., GeO_{1.5} or GeO_{1.8}). Unstable oxide materials are susceptible to reacting with the outside environment. The first substrate 202 may be formed of any material that forms an unstable oxide. In an embodiment, the first substrate 202 is formed of germanium. In an embodiment, the first substrate 202 is formed of other materials that form an unstable oxide, such as, but not limited to, gallium arsenide (GaAs), indium gallium arsenide (InGaAs), aluminum gallium arsenide (AlGaAs), and indium tin (InSb). In an embodiment, the first substrate 202 is formed of a bulk germanium substrate. In an embodiment, the first substrate 202 is formed of a semiconductor material including at least 50% Ge. In a particular embodiment, the first substrate 202 is formed of a semiconductor material including at least 90% Ge. In an embodiment, at least a top surface of the first substrate 202 is formed of a material that forms an unstable oxide when exposed to an oxidizing agent.

Next, as shown in FIG. 3B, an encapsulation layer 208 is formed on the top surface 203 of the first substrate 202. In an embodiment, the encapsulation layer 208 is formed of a material that has a stable oxide phase. That is, the material does not form an unstable oxide when exposed to an oxidizing agent such as, but not limited to, O₂ and/or H₂O. In an embodiment, the encapsulation layer 208 is formed of silicon. In a particular embodiment, the encapsulation layer 208 is epitaxial silicon. In an embodiment, the encapsulation layer 208 is epitaxial silicon and the first substrate 202 is germanium. The encapsulation layer 208 may be heteroepitaxially grown on the first substrate 202 such that the encapsulation layer 208 is locked into one or more crystallographic orientations of the first substrate 202. As such, the encapsulation layer 208 may be integrated with the lattice structure of the first substrate 202. Alternatively, the encapsulation layer 208 may be deposited as an amorphous film. The encapsulation layer 208 may be formed by any suitable process well known in the art, such as, but not limited to, chemical vapor deposition (CVD), physical vapor deposition (PVD), atomic layer deposition (ALD), and molecular beam epitaxy (MBE). In an embodiment, the encapsulation layer 208 has a thickness t1 sufficient to passivate the top surface 203 of the first substrate 202 to prevent oxidation of the first substrate 202 from occurring. Additionally, the thickness t1 of the encapsulation layer 208 is sufficient to absorb substantially all water by-products created during a wafer bonding process to prevent water from contacting the top surface 203 of the first substrate 202. In an embodiment, the thickness t1 of the encapsulation layer 208 ranges from 2 nm to 6 nm. In a particular embodiment, the thickness t1 of the encapsulation layer 208 is about 4 nm.

A first bonding oxide layer 206A is then formed on a top surface 209 of the encapsulation layer 208 as shown in FIG. 3C, thereby forming a first bonding substrate 300. The first bonding oxide layer 206A has a top surface 210. The first bonding oxide layer 206A may be formed of a material that is capable of chemically bonding to another material, such as a second bonding oxide layer 206B in FIG. 4B described below. In an embodiment, the first bonding oxide layer 206A is formed of an oxide material. For example, in one embodiment, the first bonding oxide layer 206A is a SiOₓ. In a particular embodiment, the bonding oxide layer 206A is SiO₂. The first bonding oxide layer 206A is formed to have a thickness t2 sufficient to form a strong bond when adhered to another bonding layer. The thickness t2 enables formation of a bond with a bonding strength capable of withstanding typical wafer handling forces as well as subsequent semiconductor processing. In an embodiment, the bonding strength ranges from 2-3 J/m². Additionally, in an embodiment, the thickness t2 is thin enough to enable integration with other devices, such as adjacent devices not formed above the bonding oxide layer 206A. As such, in an embodiment, the thickness t2 of the first bonding oxide layer 206A ranges from 25 nm to 75 nm. In a particular embodiment, the thickness t2 of the first bonding oxide layer 206A is 50 nm. The first bonding oxide layer 206A may be formed by any suitable deposition process, such as chemical vapor deposition (CVD) or physical vapor deposition (PVD). Alternatively, the first bonding oxide layer 206A may be formed by oxidation where a portion of the encapsulation layer 208 is consumed to form an oxide material. In an embodiment, a top portion of the encapsulation layer 208 is oxidized into the first bonding oxide layer 206A. In such embodiments, the encapsulation layer 208 is initially formed to have an equivalent thickness t3 equal to the sum of the final encapsulation layer thickness t1 and the final first oxide layer thickness t2 to compensate for consumption and volume expansion of encapsulation material during the oxidation process.

Next, in FIG. 3D, the first bonding substrate 300 is prepared for bonding. In an embodiment, preparation of the first bonding substrate 300 includes treating the top surface 210 of the first bonding oxide layer 206A to maximize a population of hydroxyl (OH) termination 302. Each OH termination 302 is an active site where a chemical bond may form. Maximizing OH termination 302 at the top surface 210 of the first bonding oxide layer 206A creates more active sites where chemical bonding may occur. As such, the first bonding oxide layer 206A may be capable of forming a stronger chemical bond. In a particular embodiment, the top surface 210 of the first bonding oxide layer 206A is activated by a plasma process or a wet chemical treatment. In an embodiment, the plasma process is an oxygen plasma process, such as an O₂ ash at room temperature. Alternatively, in an embodiment, the wet chemical treatment is an RCA clean with a chemical mixture containing hydrochloric acid. In an embodiment, maximizing OH termination 302 is performed by exposing the top surface 210 of the first bonding oxide layer 206A to a chemical solution, such as hydrogen peroxide (H₂O₂).

In FIGS. 4A-4C, a method of forming a second bonding substrate 400 is illustrated, according to embodiments of the invention. In FIG. 4A, a second substrate 204 with a top surface 205 is initially provided. The second substrate 204 may be any suitable substrate used for semiconductor device fabrication. For example, in an embodiment, the second substrate 204 is a bulk monocrystalline silicon substrate. In an alternative embodiment, the second substrate 204 is a sapphire substrate.

Thereafter, in FIG. 4B, a second bonding oxide layer 206B is formed directly on the top surface 205 of the second substrate 204 to form the second bonding substrate 400, according to embodiments of the invention. In an embodiment, the second bonding oxide layer 206B has a top surface 212. The top surface 212 of the second bonding oxide layer 206B is also a top surface 212 of the second bonding substrate 400. The second bonding oxide layer 206B may be formed of any suitable oxide layer capable of chemically bonding with the first oxide layer 206A. In an embodiment, the second bonding oxide layer 206B is formed of a same material as the first bonding oxide layer 206A. Alternatively, the second bonding oxide layer 206B is formed of a different material as the first bonding oxide layer 206A. In an embodiment, the second bonding oxide layer 206B is formed of a SiOₓ. In a particular embodiment, the second bonding oxide layer 206B is formed of SiO₂. The second bonding oxide layer 206B has a thickness t4 sufficient to enable a strong chemical bond with the first bonding oxide layer 206A in order to withstand wafer handling and subsequent semiconductor processing. In an embodiment, the thickness t4 of the second bonding oxide layer 206B ranges from 25 nm to 75 nm. In a particular embodiment, the thickness t4 of the second bonding oxide layer 206B is 50 nm.

Next, in FIG. 4C, the second bonding substrate 400 is prepared for bonding. Similar to the top surface 210 of the first bonding oxide layer 206A in FIG. 3D described above, the top surface 212 of the second bonding oxide layer 206B is treated to maximize the population of hydroxyl (OH) termination 402. Increasing the number of OH termination 402 allows the second bonding oxide layer 206B to make a strong chemical bond with the first bonding oxide layer 206A. The process of forming the strong chemical bond according to embodiments of the invention is discussed below.

FIG. 5A illustrates the first bonding substrate 300 and the second bonding substrate 400 aligned with one another for bonding. The OH termination 302 on the first bonding oxide layer 206A may be pointed towards the OH termination 402 on the second bonding oxide layer 206B.

Thereafter, as depicted in FIG. 5B, the first bonding substrate 300 is bonded with the second bonding substrate 400, thereby forming the heterogeneous bonded substrate stack 200 according to embodiments of the invention. In embodiments, the first bonding oxide 206A of the first bonding substrate 300 is bonded with the second bonding oxide 206B of the second bonding substrate 400 at a bonding site 502. As such, the first and second bonding oxides 206A and 206B fuse into a single bonded oxide layer 206. In an embodiment, the bonded oxide layer 206 has a thickness t5 that forms an adhesion strength sufficient to securely bond the first substrate 202 with the second substrate 204 such that the heterogeneous bonded substrate stack 200 can withstand typical wafer handling and subsequent semiconductor processing. Additionally, the bonded oxide layer 206 is thin enough to enable device integration with other devices, such as adjacent devices not formed above the bonding oxide layer 206B. In a particular embodiment, the thickness t5 of the bonded oxide layer 206 is the sum of the thicknesses t2 and t4 of the first bonding oxide layer 206A and the second bonding oxide layer 206B, respectively. For example, the thickness t5 of the bonded oxide layer 206 may range from 50 nm to 150 nm. In an embodiment, the thickness t5 of the bonded oxide layer 206 is 100 nm. In an embodiment, the adhesion strength created by the bonded oxide layer 206 is at least 2 J/m². In a particular embodiment, the adhesion strength is in the range of 2-3 J/m².

The first bonding substrate 300 may be bonded to the second bonding substrate 400 by any suitable direct bonding process, such as diffusion oxide bonding. In such embodiments, the bonding is performed by initially placing the top surface 210 of the first bonding substrate 300 directly onto the top surface 212 of the second bonding substrate 400. In an embodiment, pressure is not applied to maintain contact between the two substrates. Instead, Van der Waals' forces (i.e., electrostatic forces) create an initial, weak bond sufficient to temporarily hold the two substrates in place. Thereafter, a thermal anneal may be applied to chemically bond the first bonding oxide layer 206A to the second bonding oxide layer 206B to form the bonded oxide layer 206. In an embodiment, the thermal anneal is performed at a specific temperature for a certain period of time sufficient to completely fuse the first bonding oxide layer 206A to the second bonding oxide layer 206B by a chemical bond (e.g., linking cations through covalent bonds). In a particular embodiment, the thermal anneal is performed at a temperature of 300-400° C. for ½ to 1 hour under ambient pressure.

The OH termination 302 of the first bonding substrate 300 form chemical bonds with the OH termination 402 of the second bonding substrate 400 during thermal anneal, and produce water as a by-product of the chemical reaction at the bonding site 502. These water molecules may diffuse into semiconductor materials proximate to the bonding site 502, such as the second substrate 204 and the encapsulation layer 208. Because the encapsulation layer 208 is formed of a material that creates a stable oxide when exposed to an oxidizing agent, a strong bond with the bonded oxide layer 206 may be sustained even if the water molecules oxidize a portion of the encapsulation layer 208. In an embodiment, the encapsulation layer 208 absorbs the water molecules and prevents them from reaching the first substrate 202. As such, water molecules are not substantially likely to come in contact with the first substrate 202, and no unstable oxide layer is substantially likely to be formed at the interface between the first substrate 202 and the encapsulation layer 208. Therefore, a robust bond between the first substrate 202 and the second substrate 204 may be obtained to form the heterogeneous bonded substrate stack 200.

Although first and second substrates 202 and 204 are depicted as bare substrates, embodiments are not so limited. In an embodiment, the first substrate 202 includes a plurality of devices previously formed a surface of the first substrate 202 opposite of the encapsulation layer 208. Accordingly, when the first substrate 202 is bonded with the second substrate 204, the plurality of semiconductor devices is transferred onto the second substrate 204.

Additionally, the first substrate 202 and the second substrate 204 may be individual wafers. Therefore, embodiments of the present invention can be used to perform wafer-to-wafer bonding between two individual wafers. A single wafer may include a top surface formed of many different materials in a variety of arrangements. As such, bonding two separate wafers may result in some heterogeneously bonded areas and some homogeneously bonded areas.

Next, if desired, one or more semiconductor devices may be formed on the second substrate 204. The semiconductor devices may be planar transistors, non-planar transistors, or a combination of both. Non-planar transistors include finFET transistors such as double-gate transistors and tri-gate transistors. FIG. 6A illustrates an isometric view of a non-planar finFET transistor 600 formed on a substrate 204. The non-planar finFET transistor 600 includes a fin 211 attached to the substrate 204 by a bonded oxide layer 206 and an encapsulation layer 208. The fin 211 may be formed of a semiconductor material, such as germanium. A gate stack may wrap around exposed surfaces of the fin 211 and be disposed on top surfaces of the bonded oxide layer 206. The gate stack may be formed of at least two layers, a gate dielectric layer 604 and a gate electrode layer. A portion of the gate dielectric layer 604 may be disposed directly between the fin 211 and the gate electrode layer.

The gate dielectric layer 604 may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer 604 and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers 603 and at least one metal layer is a fill metal layer 602.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

As illustrated in FIG. 6A, the gate electrode may consist of a “U”-shaped structure that includes a bottom portion substantially parallel to the surface of the bonded oxide layer 206 and two sidewall portions that are substantially perpendicular to the top surface of the bonded oxide layer 206. In another implementation, at least one of the metal layers that form the gate electrode may simply be a planar layer that is substantially parallel to the top surface of the bonded oxide layer 206 and does not include sidewall portions substantially perpendicular to the top surface of the bonded oxide layer 206. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions 606 and 608 are formed within the fin 211 adjacent to the gate stack of the finFET transistor 600. A channel region 610 is disposed within the fin 211 and between the source and drain regions 606 and 608, as shown in FIG. 6B.

FIG. 6B illustrates a cross-sectional view of the non-planar finFET transistor 600 across a line along the fin 211, as shown in FIG. 6A. The non-planar finFET transistor 600 includes the gate stack formed of the gate dielectric layer 604, P- or N-type workfunction metal layer 603, and the fill metal layer 602. The gate stack is disposed directly on the fin 211. The fin 211 may include the channel region 610 disposed directly below the gate stack, and the source and drain regions 606 and 608 disposed on opposite sides of the channel region 610. Further, the fin 211 includes the encapsulation layer 208. According to embodiments of the invention, the encapsulation layer 208 allows the fin 211 to be securely attached to the bonded oxide layer 206 to form the non-planar finFET transistor 600.

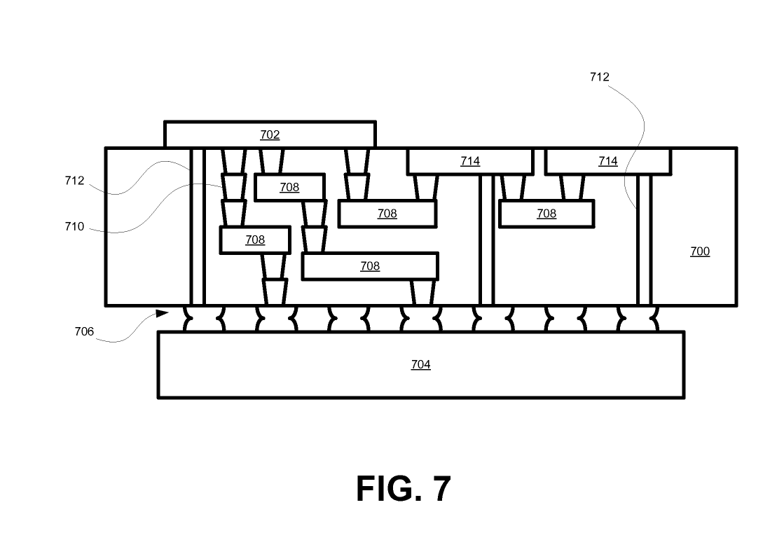

FIG. 7 illustrates an interposer 700 that includes one or more bonded structures according to embodiments of the invention. The interposer 700 is an intervening substrate used to bridge a first substrate 702 to a second substrate 704. The first substrate 702 may be, for instance, an integrated circuit die. The integrated circuit die may include a bonded structure according to embodiments of the invention. The second substrate 704 may be, for instance, a memory module, a computer motherboard, or another integrated circuit die. Generally, the purpose of an interposer 700 is to spread a connection to a wider pitch or to reroute a connection to a different connection. For example, an interposer 700 may couple an integrated circuit die to a ball grid array (B GA) 706 that can subsequently be coupled to the second substrate 704. In some embodiments, the first and second substrates 702/704 are attached to opposing sides of the interposer 700. In other embodiments, the first and second substrates 702/704 are attached to the same side of the interposer 700. And in further embodiments, three or more substrates are interconnected by way of the interposer 700. The first substrate 702 and/or the second substrate 704 may include bonded structures according to embodiments of the invention.

The interposer 700 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 708 and vias 710, including but not limited to through-silicon vias (TSVs) 712. The interposer 700 may further include embedded devices 714, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 700.

In accordance with embodiments of the invention, apparatuses or processes disclosed herein may be used in the fabrication of interposer 700.

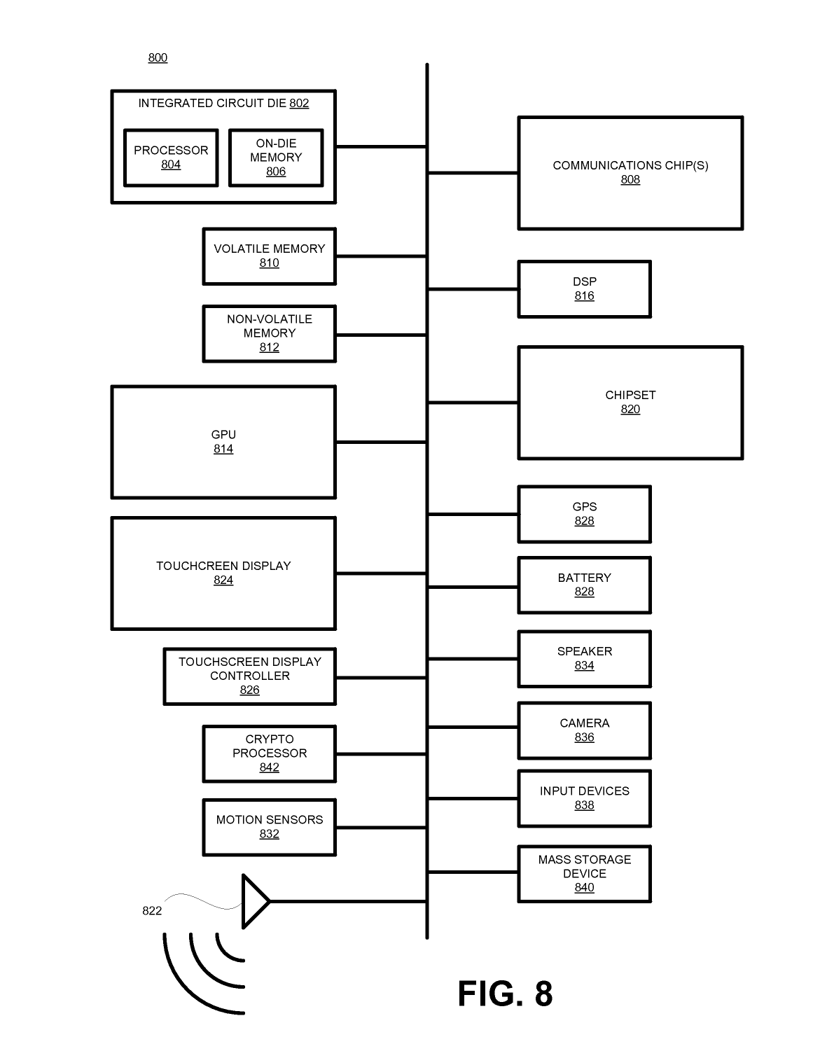

FIG. 8 illustrates a computing device 800 in accordance with one embodiment of the invention. The computing device 800 may include a number of components. In one embodiment, these components are attached to one or more motherboards. In an alternate embodiment, these components are fabricated onto a single system-on-a-chip (SoC) die rather than a motherboard. The components in the computing device 800 include, but are not limited to, an integrated circuit die 802 and at least one communication chip 808. In some implementations the communication chip 808 is fabricated as part of the integrated circuit die 802. The integrated circuit die 802 may include a CPU 804 as well as on-die memory 806, often used as cache memory, that can be provided by technologies such as embedded DRAM (eDRAM) or spin-transfer torque memory (STTM or STTM-RAM).

Computing device 800 may include other components that may or may not be physically and electrically coupled to the motherboard or fabricated within an SoC die. These other components include, but are not limited to, volatile memory 810 (e.g., DRAM), non-volatile memory 812 (e.g., ROM or flash memory), a graphics processing unit 814 (GPU), a digital signal processor 816, a crypto processor 842 (a specialized processor that executes cryptographic algorithms within hardware), a chipset 820, an antenna 822, a display or a touchscreen display 824, a touchscreen controller 826, a battery 828 or other power source, a power amplifier (not shown), a global positioning system (GPS) device 828, a compass 830, a motion coprocessor or sensors 832 (that may include an accelerometer, a gyroscope, and a compass), a speaker 834, a camera 836, user input devices 838 (such as a keyboard, mouse, stylus, and touchpad), and a mass storage device 840 (such as hard disk drive, compact disk (CD), digital versatile disk (DVD), and so forth).

The communications chip 808 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 808 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 808. For instance, a first communication chip 808 may be dedicated to shorter range wireless communications such as Wi-Fi and Bluetooth and a second communication chip 808 may be dedicated to longer range wireless communications such as GPS, EDGE, GPRS, CDMA, WiMAX, LTE, Ev-DO, and others.

The processor 804 of the computing device 800 includes one or more devices that are formed to include a heterogeneous bonded substrate stack with an encapsulation layer formed therein, that are formed in accordance with implementations of the invention. The term “processor” may refer to any device or portion of a device that processes electronic data from registers and/or memory to transform that electronic data into other electronic data that may be stored in registers and/or memory.

The communication chip 808 may also include one or more devices that are formed to include a heterogeneous bonded substrate stack with an encapsulation layer formed therein, that are formed in accordance with implementations of the invention.

In further embodiments, another component housed within the computing device 800 may contain one or more devices that are formed to include a heterogeneous bonded substrate stack with an encapsulation layer formed therein, that are formed in accordance with implementations of the invention.

In various embodiments, the computing device 800 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

In an embodiment, a method of bonding substrates includes providing a first semiconductor substrate, forming an encapsulation layer on top of the first semiconductor substrate, the encapsulation layer is formed of an encapsulation material that creates a stable oxide when exposed to an oxidizing agent, forming a first bonding layer on top of the encapsulation layer, the first bonding layer having a first top surface, providing a second semiconductor substrate, forming a second bonding layer on top of the second semiconductor substrate, the second bonding layer having a second top surface, and attaching the first semiconductor substrate to the second semiconductor substrate by bonding the first top surface to the second top surface.

In an embodiment, the first semiconductor substrate includes a first semiconductor material that creates an unstable oxide when exposed to an oxidizing agent. In an embodiment, first semiconductor material may include germanium. Additionally, in an embodiment, the encapsulation material comprises silicon. In an embodiment, the oxidizing agent is at least one of oxygen and water. In an embodiment, the method further includes surface treating the first top surface and the second top surface. In an embodiment, surface treating the first top surface and the second top surface generates hydroxyl termination at the first top surface and the second top surface. In an embodiment, surface treating the first top surface and the second top surface includes a plasma process. In an embodiment, the plasma process is an O₂ ash under ambient pressure.

In an embodiment, attaching the first semiconductor substrate to the second semiconductor substrate is performed by diffusion bonding of the first bonding layer and the second bonding layer. In an embodiment, attaching the first semiconductor strate to the second semiconductor substrate includes applying a thermal anneal.

In an embodiment, the thermal anneal is performed at a temperature of 300-400° C. for ½ to 1 hour. In an embodiment, forming the first bonding layer and the second bonding layer are formed by a deposition process. The deposition process may be a CVD process that deposits a silicon oxide material. In an embodiment, forming the first bonding layer is performed by oxidation.

In an embodiment, a bonded semiconductor structure includes a first semiconductor substrate, a second semiconductor substrate, a bonding layer disposed between the first semiconductor substrate and the second semiconductor substrate, the bonding layer attaching the first semiconductor substrate to the second semiconductor substrate, and an encapsulation layer disposed between the first semiconductor substrate and the bonding layer. In an embodiment, the first semiconductor substrate includes germanium. In an embodiment, the second semiconductor substrate includes silicon. In an embodiment, the encapsulation layer includes silicon. In an embodiment, the encapsulation layer is epitaxial silicon. In an embodiment, the encapsulation layer prevents water by-products from reaching the first semiconductor substrate. In an embodiment, the encapsulation layer has a thickness that ranges from 2 to 6 nm. In an embodiment, the bonding layer bonds the first surface to the second substrate with an adhesion strength of 2 to 3 J/m². In an embodiment, the bonding layer has a thickness in the range of 50 to 150 nm.

In an embodiment, a computer device includes a motherboard, a processor mounted on the motherboard, and a communication chip fabricated on the same chip as the processor or mounted on the motherboard, where the process includes a first semiconductor substrate, a second semiconductor substrate, a bonding layer disposed between the first semiconductor substrate and the second semiconductor substrate, the bonding layer attaching the first semiconductor substrate to the second semiconductor substrate, and an encapsulation layer disposed between the first semiconductor substrate and the bonding layer. In an embodiment, the first semiconductor substrate includes germanium. In an embodiment, the second semiconductor substrate includes silicon. In an embodiment, the encapsulation layer includes silicon. In an embodiment, the encapsulation layer is epitaxial silicon. In an embodiment, the encapsulation layer has a thickness that ranges from 2 to 6 nm.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

What is claimed is:

1. A method of bonding substrates, comprising:
providing a first semiconductor substrate;
forming an encapsulation layer on top of the first semiconductor substrate, the encapsulation layer is formed of an encapsulation material that creates a stable oxide when exposed to an oxidizing agent;
forming a first bonding layer on top of the encapsulation layer, the first bonding layer having a first top surface;
providing a second semiconductor substrate;
forming a second bonding layer on top of the second semiconductor substrate, the second bonding layer having a second top surface; and
attaching the first semiconductor substrate to the second semiconductor substrate by bonding the first top surface to the second top surface.

2. The method of claim 1, wherein the first semiconductor substrate comprises a first semiconductor material that creates an unstable oxide when exposed to an oxidizing agent.

3. The method of claim 2, wherein the first semiconductor material comprises germanium.

4. The method of claim 2, wherein the oxidizing agent is at least one of oxygen and water.

5. The method of claim 1, wherein the encapsulation material comprises silicon.

6. The method of claim 1, further comprising surface treating the first top surface and the second top surface.

7. The method of claim 6, wherein surface treating the first top surface and the second top surface generates hydroxyl termination at the first top surface and the second top surface.

8. The method of claim 1, wherein attaching the first semiconductor substrate to the second semiconductor substrate is performed by diffusion bonding of the first bonding layer and the second bonding layer.

9. The method of claim 8, further comprising applying a thermal anneal.

10. The method of claim 1, wherein forming the first bonding layer and the second bonding layer are formed by a deposition process.

11. The method of claim 10, wherein the deposition process is a CVD process that deposits a silicon oxide material.

12. The method of claim 1, wherein forming the first bonding layer is performed by oxidation.

13. A bonded semiconductor structure, comprising:
a first semiconductor substrate;
a second semiconductor substrate;
a bonding layer disposed between the first semiconductor substrate and the second semiconductor substrate, the bonding layer attaching the first semiconductor substrate to the second semiconductor substrate; and
an encapsulation layer disposed between the first semiconductor substrate and the bonding layer.

14. The structure of claim 13, wherein the first semiconductor substrate comprises germanium.

15. The structure of claim 13, wherein the second semiconductor substrate comprises silicon.

16. The structure of claim 13, wherein the encapsulation layer comprises silicon.

17. The structure of claim 13, wherein the encapsulation layer has a thickness that ranges from 2 to 6 nm.

18. The structure of claim 13, wherein the bonding layer bonds the first substrate to the second substrate with an adhesion strength of 2 to 3 J/m².

19. The structure of claim 13, wherein the bonding layer has a thickness in the range of 50 to 150 nm.

20. A computer device, comprising:
a motherboard;
a processor mounted on the motherboard; and
a communication chip fabricated on the same chip as the processor or mounted on the motherboard;
wherein the processor comprises:
a first semiconductor substrate;
a second semiconductor substrate;
a bonding layer disposed between the first semiconductor substrate and the second semiconductor substrate, the bonding layer attaching the first semiconductor substrate to the second semiconductor substrate; and
an encapsulation layer disposed between the first semiconductor substrate and the bonding layer.

21. The computer device of claim 20, wherein the first semiconductor substrate comprises germanium.

22. The computer device of claim 20, wherein the second semiconductor substrate comprises silicon.

23. The computer device of claim 20, wherein the encapsulation layer comprises silicon.

24. The computer device of claim 23, wherein the encapsulation layer is epitaxial silicon.

25. The computer device of claim 20, wherein the encapsulation layer has a thickness that ranges from 2 to 6 nm.
